(19) United States
(12) Patent Application Publication
(10) Pub. No.: US 2021/0139651 A1
(43) Pub. Date: May 13, 2021

(54) QUINOID CONJUGATED POLYMER AND PREPARATION METHOD AND APPLICATION THEREOF

(71) Applicant: DONGGUAN UNIVERSITY OF TECHNOLOGY, Guangdong (CN)

(72) Inventors: Chen LI, Guangdong (CN); Ruomeng DUAN, Guangdong (CN); Zhihong LIU, Guangdong (CN); Yanfei ZHAO, Guangdong (CN); Klaus MUELLEN, Guangdong (CN); He TIAN, Guangdong (CN); Wenshan WEI, Guangdong (CN)

(73) Assignee: DONGGUAN UNIVERSITY OF TECHNOLOGY, Guangdong (CN)

(21) Appl. No.: 17/151,623

(22) Filed: Jan. 18, 2021

Related U.S. Application Data
(63) Continuation of application No. PCT/CN2019/094502, filed on Jul. 3, 2019.

(30) Foreign Application Priority Data
Jun. 28, 2019 (CN) 201910580338.1

(51) Int. Cl. C08G 75/30

(52) U.S. Cl. CPC C08G 75/30

(57) ABSTRACT

The invention relates to a quinoid conjugated polymer and a preparation method and application thereof. The quinone conjugated polymer is a novel quinoid polymer connected by C═C double bonds and has good conductivity. The monomer used to prepare the quinoid conjugated polymer contains at least two carbonyl groups. The preparation method is simple and does not require oxidation treatment or doping. The quinoid conjugated polymer can exhibit conductivity without being oxidized or doped, can be prepared quickly and conveniently, and can be applied to optoelectronic devices, thus achieving high application value.

### CROSS-REFERENCE TO RELATED APPLICATIONS

The present application is a continuation application of International Application number PCT/CN2019/094502, filed on Jul. 3, 2019, which claims priority under 35 U.S.C § 119(a) to China Patent Application No. 201910580338.1, filed on Jun. 28, 2019. The contents of this application are incorporated herein by reference in their entirety.

### BACKGROUND

### Technical Field

The invention relates to the field of organic photoelectric materials, and more specifically, to a quinoid conjugated polymer and a preparation method and application thereof.

### Description of Related Art

In recent decades, with the continuous development of novel semiconductor devices and integrated circuit technology, the research on semiconductor materials is getting deeper and deeper. Conductive polymers can be used to prepare foldable and curved devices due to the properties of ordinary polymers, and also have good film-forming properties, which have become a research trend of semiconductor materials. Conductive polymers are commonly used in power devices, such as batteries, capacitors, electronic sensors, antistatic coatings, electromagnetic interference protection, metal anticorrosion coatings, slate printing, circuit boards, organic light-emitting diodes, solar cells, and field effect transistors.

Most organic polymers are insulators or semiconductors. Some of them can be doped to obtain charged polymers or partially quinoid polymers, and they are thus changed from insulators or semiconductors to conductive polymers, such as polypyrrole, polythiophene, polyphenylene vinylene, polyacetylene, polythiophene acetylene, polyphenylene, polyfuran, polynaphthalene, polyazulene, polyindole, polycarbazole, polyaniline, and polyphenylene sulfide. Among them, five-membered heterocyclic conjugated polymers of five-membered heterocycle such as polythiophene and polypyrrole have been widely used in various electronic devices due to their simple preparation methods and efficient processing methods. Generally, they can be conjugated polymers in which thiophene and pyrrole are connected by C—C single bonds and which are obtained by using Lewis acid to catalyze free radical oxidative polymerization. In the no-doping case, such polymers are insulators; after doping, the C—C single bond between monomers is transferred and transformed, and part of segments or the entire molecule of the polymer is transformed into a quinoid structure, and the transformation and evolution process is as follows:

[chemical structure]

In the doping case, such as in the case where polyacetylene doped with oxidizing or reducing agents such as iodine, bromine, lithium, sodium or arsenic pentafluoride, a conductivity of 105 S/cm can be obtained; and polythiophene can also achieve a conductivity of 105 S/cm in the case of oxidative doping. Through doping, part of segments of the aromatic polythiophene form a quinoid conjugated structure, which is more conducive to the transmission of electrons and improves the transmission of electrons on the molecular chain.

In order to obtain a quinoid polymer with higher conductivity, there are currently many related studies. For example, Adv. Sci, 2018, 5, 1800947 reported a method of synthesizing a polythiophene derivative, where the polymer was converted into a quinoid structure after being doped, and the conductivity was also greatly improved; when the temperature was nearly 100 degrees Celsius, the conductivity of the polymer after doping was greatly improved. TW201841921 reported a dicyanomethyl-substituted quinoid organic semiconductor material, but the synthesis of such compounds was complicated, and the final conversion of the aromatic structure into a quinoid structure must be implemented by introducing dicyanomethyl for end capping; in addition, the polymerization length of the molecules was limited; the quinoid polymers cannot be obtained through this synthesis process. WO9622317 reported a method for synthesizing polypyrrole and achieving a high conductivity by doping; the polypyrrole monomer obtained by this method is linked by C—C single bonds. Only after doping, can the polymer become a conductive polymer. JP2017206649 reported an organic semiconductor material containing quinoid segments, and this type of molecule proves that the quinoid structure can greatly reduce the energy gap of the molecule and enhance its charge transfer performance.

But so far, generally, the aromatic structure is oxidized to obtain a quinoid conjugated polymer. The preparation process is complicated, and there has not been any report on the quinoid polymer connected by C═C double bonds.

### SUMMARY

The invention is intended to overcome at least one defect (deficiency) of the above-mentioned prior art and provide a quinoid conjugated polymer, which is a novel quinoid polymer connected by C═C double bonds. With good conductivity, the quinoid conjugated polymer can be widely used in optoelectronic devices, and its preparation method is simple.

Another object of the invention is to provide a preparation method of a quinoid polymer. The preparation method of the quinoid polymer can directly obtain a quinoid conjugated polymer through a polymerization reaction, without an oxidation process, and the preparation process is simple.

The technical solutions adopted by the invention are as follows:

A quinoid conjugated polymer of the following structural formula:

[chemical structure]

wherein, R is H, alkyl with 1 to 24 carbon atoms, alkoxy with 1 to 10 carbon atoms, alkylthio with 1 to 10 carbon atoms, alkylselenyl with 1 to 10 carbon atoms, alkylsilyl with 1 to 10 carbon atoms, alkylamino with 1 to 10 carbon atoms, aryl or N, O, S-hybridized heteroaryl; X is N, O, S or C that can be joined together to form a five-membered or six-membered aromatic ring.

Further, the quinoid conjugated polymer is obtained by polymerizing the compound II monomer of the following structural formula:

[chemical structure]

wherein, R is H, alkyl with 1 to 24 carbon atoms, alkoxy with 1 to 10 carbon atoms, alkylthio with 1 to 10 carbon atoms, alkylselenyl with 1 to 10 carbon atoms, alkylsilyl with 1 to 10 carbon atoms, alkylamino with 1 to 10 carbon atoms, aryl or N, O, S-hybridized heteroaryl; X is N, O, S or C that can be joined together to form a five-membered or six-membered aromatic ring.

Further, the structural formula of the compound II monomer is any one of the following structural formulas:

[chemical structure]

Further, the aryl and/or heteroaryl has alkyl or heteroalkyl substituents.

Further, the five-membered or six-membered aromatic ring formed by Xs has substituents.

In the second aspect of the invention, a preparation method of a quinoid conjugated polymer includes the following steps:

S1: putting a monomer compound and a catalyst in a reaction vessel, and performing the operation of vacuuming and nitrogen filling;

S2: adding a solvent with a high boiling point into the reaction vessel in the presence of nitrogen;

S3: heating the solution to reflux and fully stirring; and

S4: cooling the reaction solution to precipitate a solid.

Further, the catalyst in step S1 is any one or a mixture of more of a Lawson's reagent, a derivative of Lawson's reagent, tetraphosphorus decasulfide, a mixture of hydrogen sulfide and hydrogen chloride, or other polysulfur-containing compounds.

Further, the solvent with a high boiling point in step S2 is any one or a mixture of more of trichlorobenzene, trimethylbenzene, DMSO, NMP, DMF, DMAC, DMPU, DMI, and diphenyl ether.

Further, in step S3, the solution is heated to reflux and fully stirred for 6-100 hours.

In the third aspect of the invention, the aforementioned polymer I is used as a conductive material in optoelectronic devices. In actual use, this polymer can be appropriately doped to function as a conductive material, or other quinoid conjugated polymers that substantially utilize this structure and have higher conductivity are applied to optoelectronic devices.

Compared with the prior art, the beneficial effects of the invention are as follows.

The novel quinoid conjugated polymer provided by the invention is a novel quinoid polymer connected by C═C double bonds. The quinoid polymer has good conductivity, and its preparation method is simple. It can exhibit conductivity without being oxidized or doped. It can be directly obtained by polymerization reaction, and the preparation process is quick and can be applied to optoelectronic devices; for example, it can be used as a transparent or semi-transparent electrode in organic optoelectronic devices—solar cells. These devices show better performance than the current conductive polymers, i.e., polythiophene polymers, in the market, and thus have higher application value.

### BRIEF DESCRIPTION OF THE DRAWINGS

FIG. 1 is a schematic diagram of the synthesis of the invention.

FIG. 2 is the current density-voltage curve of cell A and cell B in Example 3 of the invention.

### DESCRIPTION OF THE EMBODIMENTS

The embodiments of the invention are only used for illustrative description, and cannot be understood as a limitation of the invention. For those skilled in the art, it is understandable that some common knowledge and descriptions in the embodiments may be omitted.

### Example 1

The preparation process of the quinoid conjugated polymer in this example is as follows:

[chemical structure]

where X represents S or 0.

Further, the specific preparation method is as follows:

Phthalimide (IIa, 1 g, 6.89 mmol), Lawson's reagent (2.79 g, 6.89 mmol) and a magnetic stirrer were placed in a 500 ml two-necked flask and a condenser is installed; the flask was subjected to the operation of vacuuming and nitrogen filling through a double-row tube, and this operation was carried out three times; trichlorobenzene (200 ml) was added into the flask in the presence of nitrogen; the solution was heated to reflux and stirred for 72 hours; the reaction solution was cooled to precipitate a solid; the solid was collected by suction filtration and then washed with 30 ml of acetone three times; the solid obtained by suction filtration was dried in a vacuum oven at 100° C. for 10 hours; the solid was finely ground with an agate mortar and then extracted with a Soxhlet extractor for 48 hours; the solid in an extraction sleeve was collected and dried, and the solvent for the extraction was toluene. The dried solid was ground into powder and sublimated in a vacuum sublimation instrument for 5 hours under a pressure of 1×10⁻³ Pa at a temperature of 250° C. In the experiment, the non-volatile solid in the sublimation instrument was collected, and its final weight was 0.91 g (the yield is 91%). Solid-state Maldi-Tof mass chromatography: the measured value was 837.00; the calculated value was 837.94 (n=7, X=0). Solid-state nuclear magnetism: ¹H NMR (400 MHz) δ [ppm]=7.5, 14. ¹³C NMR (100 MHz) δ [ppm]=131.

### Example 2

The preparation process of the quinoid conjugated polymer in this example is as follows:

[chemical structure]

where X represents S or 0.

Further, the specific preparation method is as follows:

Pyridine 2,3-diimide (IIb, 1 g, 6.75 mmol), a derivative of Lawson reagent (2.73 g, 6.75 mmol) and a magnetic stirrer were placed in a 500 ml two-necked flask and a condenser is installed; the flask was subjected to the operation of vacuuming and nitrogen filling through a double-row tube, and this operation was carried out three times; trimethylbenzene (200 ml) was added into the flask in the presence of nitrogen; the solution was heated to reflux and stirred for 72 hours; the reaction solution was cooled to precipitate a solid; the solid was collected by suction filtration and then washed with 30 ml of acetone three times; the solid obtained by suction filtration was dried in a vacuum oven at 100° C. for 10 hours; the solid was finely ground with an agate mortar and then extracted with a Soxhlet extractor for 48 hours; the solid in an extraction sleeve was collected and dried, and the solvent for the extraction was toluene. The dried solid was ground into powder and sublimated in a vacuum sublimation instrument for 5 hours under a pressure of 1×10⁻³ Pa at a temperature of 250° C. In the experiment, the non-volatile solid in the sublimation instrument was collected, and its final weight was 0.85 g (the yield is 85%). Solid-state Maldi-Tof mass chromatography: the measured values were 727.07, 842.09, 958.11; the calculated values were 728.74 (n=6, X=0), 844.85 (n=7, X=0), 766.78 (n=6, X=S), 960.98 (n=8, X=0).

### Example 3

The preparation process of the quinoid conjugated polymer in this example is as follows:

[chemical structure]

where X represents S or 0.

Further, the specific preparation method is as follows:

O-pyrazine diimide (IIc, 1 g, 6.71 mmol), phosphorus decasulfide (2.71 g, 6.71 mmol) and a magnetic stirrer were placed in a 500 ml two-necked flask and a condenser is installed; the flask was subjected to the operation of vacuuming and nitrogen filling through a double-row tube, and this operation was carried out three times; diphenyl ether (200 ml) was added into the flask in the presence of nitrogen; the solution was heated to reflux and stirred for 72 hours; the reaction solution was cooled to precipitate a solid; the solid was collected by suction filtration and then washed with 30 ml of acetone three times; the solid obtained by suction filtration was dried in a vacuum oven at 100° C. for 10 hours; the solid was finely ground with an agate mortar and then extracted with a Soxhlet extractor for 48 hours; the solid in an extraction sleeve was collected and dried, and the solvent for the extraction was toluene. The dried solid was ground into powder and sublimated in a vacuum sublimation instrument for 5 hours under a pressure of 1×10⁻³ Pa at a temperature of 250° C. In the experiment, the non-volatile solid in the sublimation instrument was collected, and its final weight was 0.93 g (the yield is 93%). Solid-state Maldi-Tof mass chromatography: the measured values were 532.32, 649.26, 765.31, 882.35, 999.35, 1116.36, 1232.39, 1349.42; the calculated values were 532.07 (n=4, X=S), 649.68 (n=5, X=S), 766.78 (n=6, X=S), 883.89 (n=7, X=S), 1001.00 (n=8, X=S), 1118.11 (n=9, X=S), 1235.23 (n=10, X=S), 1352.34 (n=11, X=S), 1469.45 (n=12, X=S). Solid-state nuclear magnetism: ¹HNMR (400 MHz) δ [ppm]=9.4. ¹³C NMR (100 MHz) δ [ppm]=143,119.

TABLE 1
Conductivity results of the polymers prepared in Examples 1 to 3

| Conjugated | Conduct- | Conduct- | Conduct- | Conduct- | Average |
|---|---|---|---|---|---|
| polymer | ivity | ivity | ivity | ivity | S/cm |
| 1a | 4.367 | 4.566 | 4.785 | 4.505 | 4.0 |
| | 3.484 | 4.651 | 3.623 | 2.347 | |
| 1b | 3.247 | 3.401 | 5.291 | 5.208 | 4.1 |
| | 3.497 | 3.484 | 3.203 | 5.263 | |
| 1c | 4.926 | 5.348 | 3.906 | 4.032 | 4.1 |
| | 2.653 | 2.710 | 5.464 | 4.082 | |

The above results are the corresponding conductivity of the polymer products prepared in Examples 1 to 3, sampled for multiple times by powder compression, and tested with a four-probe conductivity tester. It can be seen from the final average value of the conductivity that the conductivity of a quinoid conjugated polymer prepared by the invention is 4.0 S/cm and above on average. It is believed that the quinoid conjugated polymer provided in the invention can be used as an organic conductive material in optoelectronic devices.

Heterojunction organic solar cells were prepared by mixing polymer PBDB-T and ITIC, in which transparent electrodes were mixtures with PEDOT:PSS and PEDOT:PSS and the product of Example 3 being 10:1, and the metal electrodes were silver, thus obtaining cell A and cell B. The specific results are as follows:

| | Voc [V] | Jsc [mA cm⁻²] | FF | PCE [%] |
|---|---|---|---|---|
| Cell A | 0.88 | 13.87 | 62.39 | 7.61 ± 0.30 |
| Cell B | 0.89 | 13.62 | 68.42 | 8.40 ± 0.25 |

Obviously, cell B has a significant improvement in cell efficiency due to the effect of Example 3.

It should be noted that the compound of the invention has poor solubility and cannot be formed into a film, resulting in low conductivity, but its conductivity is greatly improved in solvents or when the compound is dispersed; and because of the low solubility of these compounds, they are conductors in acidic solvents and cannot be subjected to nuclear magnetism measurement, so two of the examples measured solid-state nuclear magnetism.

It should be noted that the above-described embodiments are examples merely illustrative of the technical solutions of the invention and are not intended to limit the specific embodiments of the invention. Any modification, equivalent replacement and improvement made within the spirit and principle of the claims of the invention shall be included in the protection scope of the claims of the invention.

What is claimed is:

1. A preparation method of a quinoid conjugated polymer, comprising the following steps:
S1: putting a monomer compound and a catalyst in a reaction vessel, and performing an operation of vacuuming and nitrogen filling;
S2: adding a solvent with a high boiling point into the reaction vessel in the presence of nitrogen;
S3: heating the solution to reflux and fully stirring; and
S4: cooling the reaction solution to precipitate a solid;
wherein, in step S3, the solution is heated to reflux and fully stirred for 6 hours to 100 hours; in step S4, the solid crude product after the reaction is filtered and dried, is subjected to Soxhlet extraction and purification, and the solid obtained after extraction is then dried, and then sublimated under a pressure of 1×10⁻³ Pa at a temperature of 250° C. for 5 hours, and collecting a non-volatile solid, thus obtaining the quinoid conjugated polymer of the following structural formula: [chemical structure]
where n=4, 5, 6, 7, 8, 9, 10, 11 or 12; R represents H; X represents N or C connected together to form a six-membered aromatic ring.

2. The preparation method of the quinoid conjugated polymer according to claim 1, wherein the catalyst in step S1 is any one or a mixture of more of a Lawson's reagent, a derivative of Lawson's reagent, tetraphosphorus decasulfide, a mixture of hydrogen sulfide and hydrogen chloride, or other polysulfur-containing compounds.

3. The preparation method of the quinoid conjugated polymer according to claim 1, wherein, the solvent with the high boiling point in step S2 is any one or a mixture of more of trichlorobenzene, trimethylbenzene, DMSO, NMP, DMF, DMAC, DMPU, DMI, and diphenyl ether.

4. A quinoid conjugated polymer prepared by the method according to claim 1.

5. A quinoid conjugated polymer prepared by the method according to claim 2.

6. A quinoid conjugated polymer prepared by the method according to claim 3.

7. The quinoid conjugated polymer according to claim 4, used as a conductive material in optoelectronic devices.
